(19) United States
(12) Patent Application Publication
(10) Pub. No.: US 2026/0134182 A1
(43) Pub. Date: May 14, 2026

(54) Programmable Logic Device Simulations

(71) Applicants: Gregg W. Baeckler, San Jose, CA (US); Martin Langhammer, Salisbury (GB)

(72) Inventors: Gregg W. Baeckler, San Jose, CA (US); Martin Langhammer, Salisbury (GB)

(21) Appl. No.: 19/437,547

(22) Filed: Dec. 31, 2025

(51) Int. Cl. G06F 30/3308; G06F 30/327

(52) U.S. Cl. CPC G06F 30/3308; G06F 30/327

(57) ABSTRACT

In an aspect, a non-transitory, computer-readable medium, may include computer-readable instructions that, when executed by one or more processors of one or more computers, cause the one or more computers to receive a Register-Transfer Level (RTL) file that includes a system design for implementing multiple programmable logic blocks on a programmable logic device. The instructions may also cause the one or more computers to generate a modified RTL file by parsing the RTL file to remove a portion a generic simulation model included in the system design, where the portion of the generic simulation model includes a configuration for a programmable logic block that will not be reached during a behavioral simulation of the system design. The instructions may further cause the one or more computers to transmit the modified RTL file to a simulator tool.

### BACKGROUND

The present disclosure relates generally to integrated circuits and, more specifically, to systems and methods for simulating programmable integrated circuits.

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Modern electronics, such as computers, portable devices, network routers, data centers, Internet-connected appliances, and the like, tend to include at least one integrated circuit device. Integrated circuit devices may take on a variety of forms, including processors, memory devices, and programmable logic devices, to name only a few examples. In cases where the integrated circuit device is a programmable logic device, such as field programmable gate array (FPGA), the programmable logic device may include a programmable fabric of logic that may be programmed and reprogrammed after manufacturing to provide a wide variety of functionality based on a system design. In some cases, it may be desirable to use a simulation tool to simulate the behavior of the programmable logic device before implementing the system design on the programmable logic device. However, such simulation may consume a relatively large amount of resources to simulate the behavior.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit device;

FIG. 2 is a block diagram of an example of the integrated circuit device of FIG. 1;

FIG. 3 is an example of a programmable logic device simulation system including a Register-Transfer Level (RTL)-to-RTL compiler;

FIG. 4 is a flowchart depicting a method for an RTL-to-RTL compiler, such as the RTL-to-RTL compiler of FIG. 3, to generate a reduced RTL file;

FIG. 5 is an example of a reduction technique that an RTL-to-RTL compiler, such as the RTL-to-RTL compiler of FIG. 3, may use for pruning portions of a system design to generate a reduced RTL file;

FIG. 6 is a flowchart depicting a method of generating RTL suggestions for a graphical user interface (GUI) based on one or more reduction techniques;

FIG. 7 is an example of a GUI that displays RTL suggestions, such as the RTL suggestions generated in the FIG. 6 flowchart; and

FIG. 8 is a block diagram of a data processing system that may incorporate the systems and methods of this disclosure.

### DETAILED DESCRIPTION OF SPECIFIC EMBODIMENTS

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

As mentioned, programmable logic devices may include a programmable fabric that a designer (e.g., anyone configuring the programmable logic device) may interact with to cause the programmable logic device to perform a wide variety of operations. In some cases, a designer may describe a system design for a programmable logic device using Register-Transfer Level (RTL) code based on hardware description languages (HDLs), such as Verilog and/or very high speed integrated circuit hardware description language (VHDL). For example, the designer may instantiate embedded programmable logic blocks in the system design (e.g., a digital hardware design, a configuration, a circuit design) using the RTL code. Additionally or alternatively, designers may implement embedded programable logic blocks in the system design based on intellectual property (IP) blocks (e.g., predefined logic or circuitry that may be retrieved from a catalog) using an IP parameterization tool. In these ways, the designer may use RTL coding to define instantiations of different embedded programmable logic blocks in the programmable fabric of the programmable logic device. These techniques may be used in modern programmable logic devices to define thousands of embedded programmable logic blocks, such as digital signal processing (DSP) blocks, memory blocks, and/or the like, that may perform various operations. Additionally, each embedded programmable logic block may include many sub-components. A DSP block, for example, may include multiple tensor columns of multipliers, adder trees, and/or the like. As a result, each embedded programmable logic block that is included in the system design may be associated with a vendor provided simulation model. The simulation models may define generic configuration options and functionalities for the embedded programmable logic blocks. In some cases, the simulation models may include predefined RTL code (e.g., in Verilog or another suitable HDL) that may define the configurations options and functionalities for the embedded programmable logic blocks. In some aspects, the simulation models may be included in the system design (e.g., imported into the system design, merged with the system design). However, in other aspects, the system design may refer to implementations of the programmable logic blocks (e.g., the system design includes the designer instantiations of the programmable logic device that may be described in HDL and/or received from the IP parameterization tool, such that the system design refers to a designer implementation (e.g., user logic) of an intended behavior of programmable logic to be simulated). In these aspects, the simulation models may include separate RTL code (e.g., independent from the system design) and may be included in a common RTL file with the system design. In either case, an RTL file may include both the system design and one or more applicable simulation models.

It is often desirable for designers to simulate a behavior of the programmable logic device before configuring the programmable logic device. Simulating portions of a system design may provide a time and cost efficient means for debugging intended functions of the programmable logic device, evaluating the performance of the programmable logic device, testing logic before dealing with implementation-based constraints associated with the physical programmable logic devices, and/or provide many additional benefits. To simulate the behavior of the programmable logic device, designers may use simulator tools (e.g., Electronic Design Automation (EDA) simulators). Simulator tools may refer to software platforms (e.g., Synopsys Verilog Compiler Simulator (VCS) provided by Synopsys, Mentor QuestaSim provided by Siemens Digital Industries Software) that may simulate the behavior of the programmable logic device based on certain conditions (e.g., an input state, parameterization information). In order for the simulator tool to simulate the behavior of the programmable logic device with the designer's system design (e.g., to simulate IP that may be implemented on the programmable logic device), the simulator tool may compile and execute the RTL code, which may include simulation models for the embedded programmable logic blocks.

In some cases, the RTL code may contain thousands of lines of code that may be inapplicable to instantiations of the embedded programmable logic block that are included in the system design. Indeed, designer-specific instantiations of the embedded programmable logic blocks may not use every configuration included in the simulation models. Accordingly, the simulator tool may parse many unnecessary lines of RTL as it iteratively evaluates the behavior of the programmable logic device and generates a series of simulation results (e.g., based on different states of the programmable logic device). At each iteration of the simulation (e.g., based on clock ticks; based on changed states), the simulator tool may demand a current input state and parameterization information to generate a result. For system designs that include thousands of embedded programmable logic blocks, the simulator tool may trace the software path for each embedded programmable logic block at each iteration (e.g., in parallel). As will be appreciated, simulating system designs in this manner may demand extensive computing resources and timing resources.

With this in mind, the present disclosure provides systems and methods for improving computer resource usage and timing for programmable logic device simulations. More specifically, the present disclosure provides systems and methods that may limit (e.g., reduce relative to other systems) the source material that is provided to the simulator tool and used to simulate the behavior of a programmable logic device. Indeed, aspects of the present disclosure are directed to an RTL-to-RTL compiler that may receive the RTL-based system design from a designer and generate a reduced RTL file (e.g., modified RTL file) that may then be compiled and executed by the simulator tool. The RTL-to-RTL compiler may generate the reduced RTL file based on various reduction techniques, which may be predefined and deterministic pattern recognition algorithms for removing or substituting portions of the system design (e.g., the received RTL file). As will be described in more detail throughout this disclosure, the RTL-to-RTL compiler may generate a reduced RTL file in cases where the system design (e.g., the received RTL file) may be incomplete and/or include errors (e.g., syntax errors). Additionally or alternatively, the RTL-to-RTL compiler may generate the reduced RTL file based on a portion of the system design (e.g., the received RTL file). In some aspects, the RTL-to-RTL compiler may not translate between RTL and other languages associated with the compilers internal logic (e.g., as may be common in other systems). Instead, the RTL-to-RTL compiler may generate the reduced RTL file and transmit the reduced RTL file to the simulator tool to be compiled and executed during a simulation. In these ways, the RTL-to-RTL complier may provide multiple benefits. For example, the simulator tool may be able to run a simulation of the programmable logic device based on much less information than other systems. Put differently, portions of the RTL that are unrelated to a desired system design and/or system function may be removed by the RTL-to-RTL compiler to reduce the processing load on the simulator tools. Further, the reduced RTL file may be much shorter and easier to debug than prior systems. In at least these ways, the current techniques may provide a benefit in the functioning of a compiler and a simulator tool and improve designer experience for debugging programmable logic device simulations.

In another aspect, similar techniques for improving programmable logic device simulations may be provided on a graphical user interface (GUI). Because the RTL-to-RTL compiler may generate the reduced RTL file in RTL format (e.g., rather than another language associated with the compiler), the RTL reduction techniques associated with the RTL-to-RTL compiler may be used to provide GUI suggestions (e.g., instructions) for improving computer resource utilization and expected simulation run times as the designer drafts the system design (e.g., in RTL code in a text editor). In at least these ways, the techniques provided by the RTL-to-RTL compiler may also be implemented on a GUI to provide an additional or alternative benefit.

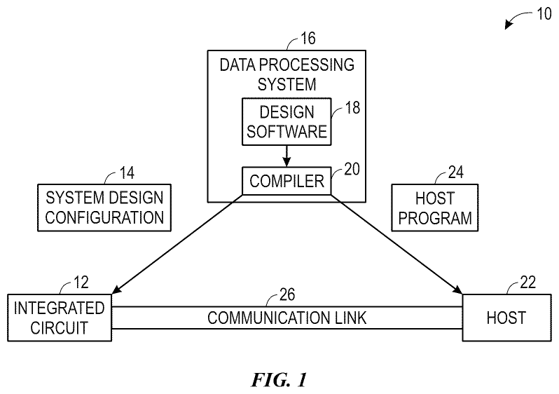

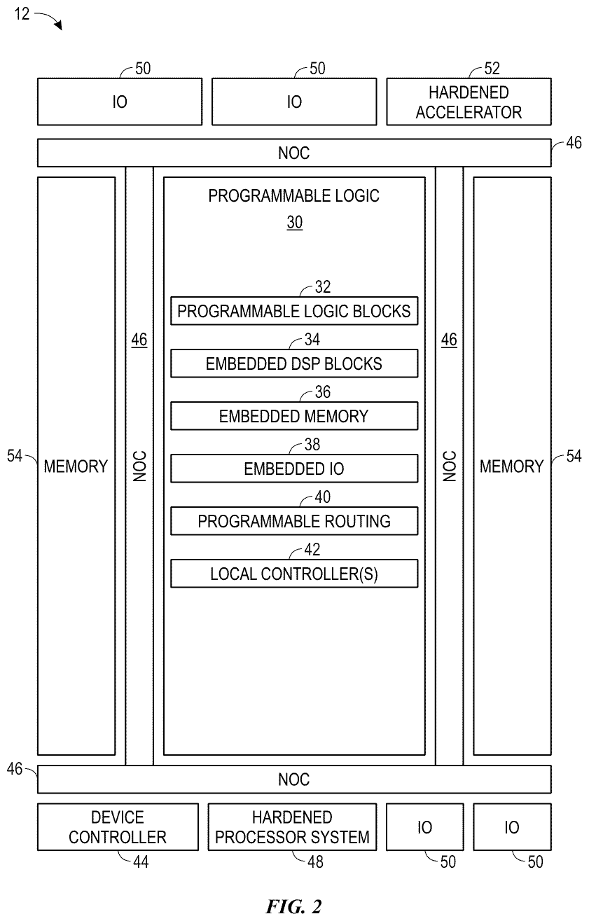

With this in mind, FIGS. 1 and 2 provide a background on the programmable integrated circuit devices. For example, FIG. 1 illustrates a block diagram of a system 10 that may be used to program an integrated circuit device 12, such as an FPGA (e.g., Agilex™, Stratix®, Arria®, MAX®, or Cyclone® devices by Altera® Corporation), with such a system design using a system design configuration 14. Note that, while this disclosure largely refers to the integrated circuit device 12 as being a programmable logic device, such as an FPGA, in some embodiments, the integrated circuit device 12 may also include a one-time programmable device or structured application specific integrated circuit (ASIC), such as an Intel® eASIC™ device by Intel® Corporation. In other examples, the integrated circuit device 12 may be any suitable integrated circuit that is manufactured to have a particular system design with circuitry to perform desired data processing operations. The integrated circuit device 12 may be a single monolithic integrated circuit or a multi-die system of integrated circuits. The integrated circuit device 12 may include a single integrated circuit, multiple integrated circuits in a package, or multiple integrated circuits in multiple packages communicating remotely (e.g., via wires, via traces) and may be referred to as an integrated circuit device or an integrated circuit system whether formed from a single integrated circuit or multiple integrated circuits in a package.

A designer may desire to implement the system design 14 (sometimes referred to as a circuit design or configuration) to perform a wide variety of possible operations on the integrated circuit device 12. In some cases, the designer may specify a high-level program to be implemented, such as an OPENCL® program that may enable the designer to more efficiently and easily provide programming instructions to configure a set of programmable logic cells for the integrated circuit device 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve than designers that are required to learn unfamiliar low-level hardware description languages to implement new functionalities in the integrated circuit device 12.

In a configuration mode of the integrated circuit device 12, a designer may use a data processing system 16 (e.g., a computer including a data processing system having a processor and memory or storage) to implement high-level designs (e.g., a system user design) using design software 18 (e.g., executable instructions stored in a tangible, non-transitory, computer-readable medium such as the memory or storage of the data processing system 16), such as a version of Altera® Quartus® by Altera Corporation. The data processing system 16 may use the design software 18 and a compiler 20 to convert the high-level program into a lower-level description (e.g., a configuration program, a bitstream) as the system design configuration 14. The compiler 20 may provide machine-readable instructions representative of the high-level program to a host 22 and the system design configuration 14 to the integrated circuit device 12. Additionally or alternatively, the compiler 20 may include an RTL-to-RTL compiler that compiles RTL as previously noted or the RTL-to-RTL compiler may be separate from the compiler 20. As will be discussed in more detail below, the system design configuration 14 may include an application program that may be associated with one or more functions. In particular, the application program may be configured to run the one or more functions on the data processing system 16. For example, the data processing system 16 may execute the application program.

Additionally or alternatively, the host 22 running the host program 24 may control or implement the system design configuration 14 onto the integrated circuit device 12. For example, the host 22 may communicate instructions from the host program 24 to the integrated circuit device 12 via a communications link 26 that may include, for example, direct memory access (DMA) communications or peripheral component interconnect express (PCIe) communications. The designer may use the design software 18 to generate and/or to specify a low-level program, using low-level tools such as the low-level hardware description languages described above. Further, in some embodiments, the system 10 may be implemented without a separate host 22 or host program 24. Thus, embodiments described herein are intended to be illustrative and not limiting.

The integrated circuit device 12 may take any suitable form that may implement the system design configuration 14. In one example shown in FIG. 2, the integrated circuit device 12 may include programmable logic circuitry 30, which may include a two-dimensional array of many different functional blocks, such as programmable logic blocks 32, embedded digital signal processing (DSP) blocks 34, embedded memory blocks 36, and embedded input-output blocks 38. In many cases, there may be rows or columns of these functional blocks that may be programmably connected to one another using programmable routing 40.

The programmable logic blocks 32 may be programmed to implement a wide variety of logic circuitry. The programmable logic blocks 32 may include a number of adaptive logic modules (ALMs), which may take the form of lookup tables (LUTs) that can be programmed to implement a logic truth table, effectively enabling any of the programmable logic blocks 32 to implement any desired logic circuitry when configured with the system design configuration 14. The programmable logic blocks 32 and are sometimes referred to as logic array blocks (LABs) or configurable logic blocks (CLBs).

The embedded DSP blocks 34, embedded memory blocks 36, and embedded IO blocks 38 may be distributed around the programmable logic blocks 32. For example, there may be several columns of programmable logic blocks 32 for every column of DSP blocks 34, column of embedded memory blocks 36, or column of embedded IO blocks 38. The embedded DSP blocks 34 may include “hardened” circuits that are specialized to efficiently perform certain arithmetic operations. This is in contrast to “soft logic” circuits that may be programmed into the programmable logic blocks 32 to perform the same functions, but which may not be as efficient as the hardened circuits of the DSP blocks 34. The embedded memory blocks 36 may include dedicated local memory (e.g., blocks of 20 KB, blocks of 1 MB). The embedded IO blocks 38 may allow for inter-die or inter-package communication. The embedded DSP blocks 34, embedded memory blocks 36, and embedded IO blocks 38 may be accessible to the programmable logic blocks 32 using the programmable routing 40.

The various functional blocks of the programmable logic circuitry 30 may be grouped into programmable regions, sometimes referred to as logic sectors, that may be individually managed and configured by corresponding local controllers 42 (e.g., sometimes referred to as Local Sector Managers (LSMs)). The grouping of the programmable logic circuitry 30 resources on the integrated circuit device 12 into logic sectors, logic array blocks, logic elements, or adaptive logic modules is merely illustrative. In general, the integrated circuit device 12 may include functional logic blocks of any suitable size and type, which may be organized in accordance with any suitable logic resource hierarchy. Indeed, there may be other functional blocks (e.g., other embedded application specific integrated circuit (ASIC) blocks) than those shown in FIG. 2.

Before continuing, it may be noted that the programmable logic circuitry 30 of the integrated circuit device 12 may be controlled by programmable memory elements sometimes referred to as configuration random access memory (CRAM). Memory elements may be loaded with configuration data (also called programming data or a configuration bitstream) that represents the system design configuration 14. Once loaded, the memory elements may provide a corresponding static control signal that controls the operation of an associated functional block. In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, and the like. The configuration memory elements may use any suitable volatile and/or non-volatile memory structures such as random-access-memory (RAM) cells, fuses, antifuses, programmable read-only-memory (ROM) memory cells, mask-programmed, laser-programmed structures, or combinations of structures such as these.

A device controller 44, sometimes referred to as a secure device manager (SDM), may manage the operation of the integrated circuit device 12. The device controller 44 may include any suitable logic circuitry to control and/or program the programmable logic circuitry 30 or other elements of the integrated circuit device 12. For example, the device controller 44 may include a processor (e.g., an x86 processor or a reduced instruction set computer (RISC) processor, such as an Advanced RISC Machine (ARM) processor or a RISC-V processor) that executes instructions stored on any suitable tangible, non-transitory, machine-readable media (e.g., memory or storage). Additionally, or alternatively, the device controller 44 may include a hardware finite state machine (FSM). The device controller 44 may provide other functions, such as serving as a platform for virtual machines that may manage the operation of the integrated circuit device 12.

A network-on-chip (NOC) 46 may connect the various elements of the integrated circuit device 12. The NOC 46 may provide rapid, packetized communication to and from the programmable logic circuitry 30 and other blocks, such as a hardened processor system 48, high-speed input-output (IO) blocks 50, a hardened accelerator 52, and local device memory 54. The integrated circuit device 12 may include the hardened processor system 48 when the integrated circuit device 12 takes the form of a system-on-chip (SOC). The hardened processor system 48 may include a hardened processor (e.g., an x86 processor or a reduced instruction set computer (RISC) processor, such as an Advanced RISC Machine (ARM) processor or a RISC-V processor) that may act as a host machine on the integrated circuit device 12. The high-speed IO blocks 50 may enable communication using any suitable communication protocol(s) with other devices outside of the integrated circuit device 12, such as a separate memory device. The hardened accelerator 52 may include any hardened application-specific integrated circuitry (ASIC) logic to perform a desired acceleration function. For example, the hardened accelerator 52 may include hardened circuitry to perform cryptographic or media encoding or decoding. The memory 54 may provide local device memory (e.g., cache) that may be readily accessible by the programmable logic circuitry 30.

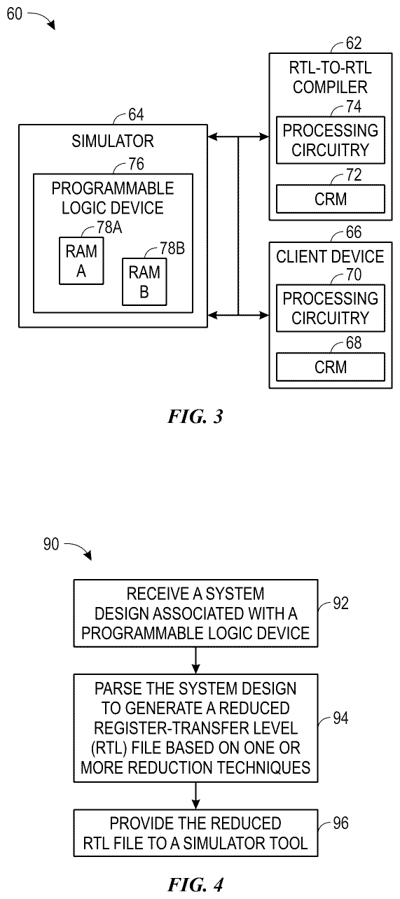

With this in mind, FIG. 3 is an example of a programmable logic device simulation system including an RTL-to-RTL compiler. The simulation system 60 may include the RTL-to-RTL compiler 62, which may be communicatively coupled to a simulator tool 64 and/or a client device 66. By way of background, the client device 66 may be any suitable computing device (e.g., a laptop, a mobile phone, a server) that may include memory 68 (computer-readable medium (CRM)) and processing circuitry 70. The memory 68 may include instructions thereon that, when executed by processing circuitry 70, cause the client device 66 to perform various functions, such as communicating with the RTL-to-RTL compiler 62 and/or the simulator tool 64. In some aspects, the client device 66 may host or access a design software 18, such as a version of Altera® Quartus® by Altera Corporation. In some aspects, the client device 66 may use the design software 18 to generate a system design for an integrated circuit device 12 (e.g., a programmable logic device).

The RTL-to-RTL compiler 62 may also be any suitable computing device that may include memory 72 (computer-readable medium (CRM)) and processing circuitry 74 including instructions thereon that, when executed by processing circuitry 74, cause the RTL-to-RTL compiler 62 to perform various functions, such as parsing a simulation model, generating a reduced RTL file, and transmitting the reduced RTL file to the simulator tool 64. In other aspects, the RTL-to-RTL compiler 62 may be a program (e.g., a cloud application) that may run on the client device 66 and/or the simulator tool 64.

As described above, the simulator tool 64 may refer to a software platform that may provide a simulation for a programmable logic device 76. In some aspects, the simulator tool 64 may be a computing device (e.g., having a memory and a processing circuitry). However, in other aspects, the simulator tool 64 may be a program or an application that may communicate (e.g., send and receive data) with the RTL-to-RTL compiler 62 and/or the client device 66.

Turning now to the instant example, in the simulator tool 64, a programmable logic device 76 may be designed to include multiple embedded programmable logic blocks. In this example, the programmable logic device 76 includes two Random Access Memory (RAM) blocks 78, individually referred to as RAM blocks 78A and 78B (e.g., that may correspond to the embedded memory blocks 36). The designer may desire to implement RAM block 78A differently than RAM block 78B. For example, the designer may draft a system design in RTL code using an HDL language (e.g., Verilog or VHDL) to define an instantiation for both RAM blocks 78. In other aspects, the designer may use an IP parameterization tool to implement both RAMs blocks 78. An IP parameterization tool (e.g., Platform Designer provided by Altera Corporation) may refer to a platform that enables designers to define an instantiation of predefined programmable logic blocks (e.g., IP cores) in the programmable fabric of the programmable logic device 76. In either case, for purposes of this example, the RAM block 78A may be designed to operate in a dual-port mode with no error correction (ECC). Conversely, the RAM block 78B may be designed to operate in a single port mode with ECC. Without aspects of the present disclosure, the RTL code for RAM block 78A and RAM block 78B may include a common simulation model. Because the simulation model may be generic (e.g., applicable to many different RAM instantiations), it may contain thousands of lines of code (e.g., 2,000 lines of Verilog, 5,000 lines of Verilog). By way of specific example, the simulation model may describe a wide array of data widths (e.g., 8 bit to 40 bit), error correction enablement and specification, and any other suitable modes (e.g., reading and writing data bits of varying widths). As may be appreciated, compiling and simulating both RAM blocks 78 based on the generic simulation model may provide inefficiencies as only a small subset of the defined configurations may be applicable to the designer's desired instantiation of each RAM block 78. For example, it may be inefficient for the simulator tool 64 to repeatedly parse a portion of the RTL code for RAM block 78A related to ECC as the RAM block 78A does not include ECC. Moreover, the simulator tool 64 may parse these lines at each iteration of the simulation. Thus, the simulator tool 64 may read and analyze millions of lines related to undesired and/or inapplicable configurations throughout the course of a simulation.

The RTL-to-RTL compiler 62 may address this inefficiency by generating an executable RTL file that reduces (e.g., limits) any unnecessary configurations. More specifically, the RTL-to-RTL compiler 62 may use input states and parameterization information to generate a parse tree of the RTL code (e.g., of the system design). The RTL-to-RTL compiler 62 may then traverse the parse tree and prune any branches that are not reached during the simulation. The RTL-to-RTL compiler 62 may generate a reduced RTL file that includes instantiation specific configurations and operations for each RAM block 78. Put differently, the RTL-to-RTL compiler 62 may remove programmable logic block configurations from the simulation models for programmable logic functions that may be unused (e.g., according to a designer implementation of the programmable logic block) or otherwise missing from the design/user logic. Then, as the simulator tool 64 performs multiple iterations of a simulation, it may parse the reduced RTL files. At scale, in programmable logic devices 76 that include thousands or millions of the embedded programmable logic blocks, these techniques may provide a significant benefit to simulator run time (e.g., timing increases of up to 75% compared to other systems).

Turning to a more detailed explanation for the process of generating the reduced RTL files, FIG. 4 is a flowchart depicting a method 90 for the RTL-to-RTL compiler 62 to generate a reduced RTL file from a system design. Although the following description of the method 90 is described as being performed by the RTL-to-RTL compiler 62 of FIG. 3, it should be noted that any suitable device capable of receiving and processing data may perform the method 90 described herein. In addition, although the method 90 is described in a particular order, it should be understood that the method 90 may be performed in any suitable order and may exclude one or more of the blocks described herein.

At block 92, the RTL-to-RTL compiler 62 may receive a system design. The system design may refer to a design of the entire programmable logic device 76 or a small portion of the programmable logic device 76 (e.g., a portion of the programmable logic circuitry 30). To provide one example, a system design may refer to logic for performing a specific task, such as complex multiplication operations, on the programmable logic device 76. The RTL-to-RTL compiler 62 may receive the system design from client device 66. For example, a designer may create the system design using RTL code (e.g., in a text-editor) and/or using IP parameterization tools. Additionally, the system design may include simulation models for each embedded programmable logic block. As mentioned the simulation models may be defined by vendors and may be generic to provide a wide variety of configurations for each embedded programmable logic block that may be implemented on the programmable logic device 76. For example, the vendor provided simulation models may include configurations for embedded memory blocks, embedded DSP blocks, and/or any other suitable programmable logic block. Accordingly, the system design may include an implementation (e.g., an instantiation) of multiple programmable logic blocks (e.g., defined by a designer, retrieved from an IP parameterization tool) and a simulation model for each programmable logic block that defines multiple configurations and behaviors for the programmable logic block. The system design may, therefore, specify a behavior for the programmable logic blocks that may be simulated and potentially configured on the programmable logic device 76.

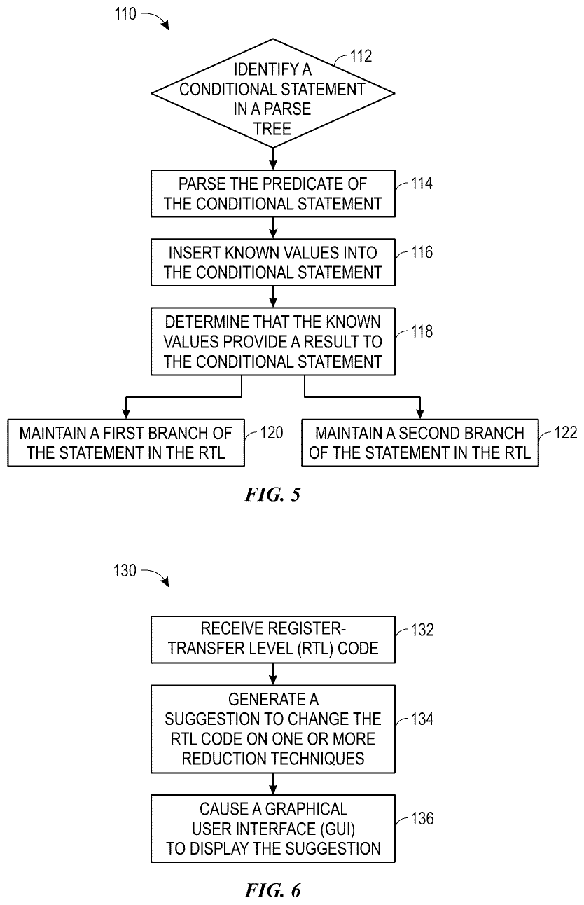

At block 94, the RTL-to-RTL compiler 62 may parse the system design to generate a reduced RTL file based on one or more reduction techniques. The RTL-to-RTL compiler 62 may, for example, use the system design to identify a number of input states. The RTL-to-RTL compiler 62 may use the input states from the system design and parameterization information (e.g., in the vendor provided simulation model) to determine whether any branch of the system design (e.g., the vendor provided simulator models in the RTL code) is inapplicable to a particular embedded programmable logic block. More specifically, the RTL-to-RTL compiler 62 may generate a parse tree for the system design based on the input states and the parameterization information. The RTL-to-RTL compiler 62 may then traverse the parse tree to prune any branches that may not be reached during a simulation using those input states and/or the parameterization information (e.g., based on the implementations of the programmable logic device included in the system design). In some aspects, the RTL-to-RTL compiler 62 may use predefined reduction techniques to identify portions of the parse tree that may be pruned (e.g., configurations included in the vendor provided simulation models that may be removed based on the designer implemented functions or behaviors of programmable logic blocks not using such functions or behaviors). As will be discussed in more detail with reference to FIG. 5, one possible reduction technique may be substituting inapplicable portions of conditional statements (e.g., if-else loops). However, in additional or alternative aspects, the RTL-to-RTL compiler 62 may use any suitable reduction technique for generating the reduced RTL file. The reduction techniques may refer to deterministic processes that may use pattern matching algorithms to identify portions of the system design (e.g., the original RTL code) that may not be reached and/or portions of the system design that may be simplified (e.g., substituted for alternative RTL code). In other words, the RTL-to-RTL compiler 62 may remove any portions of simulation models or other aspects of the RTL code that may be included in the system design but may not be reached or exercised by calling circuitry of the simulator tool 64 during the execution of a simulation. To provide a few examples, in some instances a reduction technique may include eliminating models based on HDL (e.g., Verilog) parameters. For example, the RTL-to-RTL compiler 62 may remove test and/or diagnostic models which are present in a simulation model but are not used by the designer (e.g., in the system design). In another instance, a reduction technique may include simplifying (e.g., minimizing, compressing) expressions that the designer or simulation models could have drafted more succinctly. For example, the RTL-to-RTL compiler 62 may perform Boolean refactoring, duplicate extraction, and/or the like on certain expressions included in the RTL code. In another instance, a reduction technique may include reducing RTL code based on observability metrics (e.g., control don't care values and/or expressions) indicating that one possible branch of the RTL code cannot occur in response to another branch occurring. For example, if a first branch of RTL code and a second branch of RTL code are mutually exclusive, then only one branch may be maintained. It should be noted that the observability metrics may be different than hardware implementations where in many cases both branches may be computed and one may be passed at run time. Indeed, for simulations only the first or second branch may be used to compute a desired value. In some instances, a reduction technique may include removing RTL code based on designer guidance and/or the results of previous simulations and/or RTL-to-RTL compiler 62 reductions. For example, the RTL-to-RTL compiler 62 may remove RTL code associated with manufacturing defects in a memory array and RAM redundancy objects (e.g., which may be necessary for hardware implementations but stipulated for simulations). Additionally or alternatively, a reduction technique may include genericizing (e.g., upleveling) detailed implementations. For example, the RTL-to-RTL compiler 62 may replace a transistor-level implementation in RTL code that includes multiple components with a more abstract expression (e.g., that is easier for programming languages (e.g., C) to process). As another example of genericizing detailed implementations, the RTL-to-RTL compiler 62 may replace bit oriented expressions with word oriented expressions that may be preferred for central processing unit (CPU) emulation. In these ways, the RTL-to-RTL compiler 62 may replace a portion of the RTL code with an alternative RTL expression (e.g., an RTL statement, an RTL string) in the reduced RTL file. In some cases, a reduction technique may include analyzing previous use cases of simulation models. For example, if an embedded programmable logic block does not exercise a capability in previous iterations of a simulation, then the RTL-to-RTL compiler 62 may remove the capability from the RTL code. For example, if a particular RAM block does not exercise error correction (ECC) in previous simulations, the RTL code associated with ECC for the particular RAM block may be removed from the RTL code. The RTL-to-RTL compiler 62 may use these reduction techniques individually or in combination to reduce and/or modify the RTL code so that it may be simulated more efficiently. In these ways, the RTL-to-RTL compiler 62 may leverage existing knowledge of HDL tools and syntax to generate the reduced RTL file according to a deterministic process. In some aspects, the RTL-to-RTL compiler 62 may be designed conservatively. In these aspects, the RTL-to-RTL compiler 62 may not remove or substitute a portion of the vendor provided simulation file unless it satisfies one or more conditions of a predefined reduction technique.

In some aspects, at block 94, the RTL-to-RTL compiler 62 may parse an incomplete system design and/or a system design that includes one or more syntax errors. For example, the RTL-to-RTL compiler 62 may parse an incomplete system design and generate a reduced RTL file based on one or more portions of the incomplete system design that were fully defined (e.g., not affected by the incomplete system design). Likewise, the RTL-to-RTL compiler 62 may parse a system design that includes one or more errors and generate a reduced RTL file based on one or more portions of the system design that did not include errors and/or were not affected by the errors. Additionally or alternatively, in some aspects the RTL-to-RTL compiler 62 may generate the reduced RTL file as it parses the system design. For example, the RTL-to-RTL compiler 62 may parse a portion of the system design simultaneously while removing portions of the system design that may not be reached and/or substituting portions of the system design that may be simplified. In this way, the RTL-to-RTL compiler 62 includes a parallel processing aspect that may further increase the efficiency of the operations described herein.

At block 96, the RTL-to-RTL compiler 62 may provide the reduced RTL file to a simulator tool 64. The simulator tool 64 may compile and execute the reduced RTL file to run a behavioral simulation, such as a behavioral instance model (BIM). The simulations may enable the designer to monitor and debug the behavior of the system design before physically implementing (e.g., configuring) the system design on the programmable logic device 76. In at least these ways, the simulator tool 64 may perform the simulations in a more time efficient manner based on the reduced RTL file that may remove a significant portion of inapplicable code associated with the vendor provided simulation models.

Turning now to an example of the preceding method 90, FIG. 5 is an example of a reduction technique that the RTL-to-RTL compiler 62 may use for pruning portions of a simulation model to generate the reduced RTL file. In particular, FIG. 5 provides a method 110 of a reduction technique for substituting certain portion of a conditional statement that may be included in the system design. Although the following description of the method 110 is described as being performed by the RTL-to-RTL compiler 62 of FIG. 3, it should be noted that any suitable device capable of receiving and processing data may perform the method 110 described herein. In addition, although the method 110 is described in a particular order, it should be understood that the method 110 may be performed in any suitable order and may exclude one or more of the blocks described herein.

As described with reference to FIG. 4, the RTL-to-RTL compiler 62 may initially receive the RTL code for a system design and generate an expanded parse tree for the system design. At block 112, the RTL-to-RTL compiler 62 may identify a conditional statement in the parse tree. As used herein, a conditional statement may refer to any comparison that may split into multiple branches. For example, an if-else statement in the parse tree may be a conditional statement. The RTL-to-RTL compiler 62 may identify the conditional statements based on a syntax of the conditional statement.

At block 114, the RTL-to-RTL compiler 62 may parse the predicate of the conditional statement. In some aspects, the RTL-to-RTL compiler may determine one or more values (e.g., variables; references) in the conditional statement and/or one or more conditions (e.g., numerical comparisons; Boolean expressions) included in the conditional statement.

At block 116, the RTL-to-RTL compiler 62 may insert (e.g., in-line; substitute) known values into the conditional statement. In some aspects, the RTL-to-RTL compiler 62 may include a data source (e.g., a table) of known values. Designers may add known values to the data source manually, the RTL-to-RTL compiler 62 may identify known values based on a specific deployment (e.g., based on a signal port), and/or the RTL-to-RTL compiler 62 may identify known values as it traverses the parse tree. The RTL-to-RTL compiler 62 may determine known values based on whether values within the parse tree may change (e.g., based on a condition of a simulation). If the values are known (e.g., they do not change; they are deterministic in response to certain conditions included in the parse tree), then the RTL-to-RTL compiler 62 may, at block 118, evaluate the conditional statement based on the known values.

At blocks 120 and 122 the RTL-to-RTL compiler 62 may then maintain the first branch of the statement or the second branch of the statement based on an evaluation of the conditional statement. To provide an illustrative example, Code Excerpt 1 includes a portion of a system design (e.g., RTL code in Verilog) for implementing arithmetic operations in a programmable logic device 76.

Code Excerpt 1

```
if (op_mode == OP_MUL) begin
  result <= data_a * data_b;
end
// Next priority: Subtraction
else if (op_mode == OP_SUB) begin
  result <= data_a − data_b;
end
// Next priority: Addition
else if (op_mode == OP_ADD) begin
  result <= data_a + data_b;
end
// Lowest priority / default case
else begin
  result <= 8′hFF;
```

In some cases, the RTL-to-RTL compiler 62 may identify that the “op_mode” is a known value. For example, the RTL-to-RTL compiler 62 may determine that the “op_mode” is a known value based on an input wiring of a corresponding circuit. If, for example, the “op_mode” is known to be an addition operation (e.g., OP_ADD), then Code Excerpt 1 may be rewritten as “result<=data_a+data_b.” As may be appreciated, the reduced RTL file may not include the higher priority comparisons, which may enable a simulator tool 64 to perform two less comparisons at each iteration of a simulation.

Although the reduction technique described in this method 110 relates to conditional statements, many other reduction techniques may also be defined and used by the RTL-to-RTL compiler 62 as described above. For example, in certain aspects, variables that are defined up to a certain size may be substituted if that configuration is not used or supported by at least one instantiation of the system design, error checking and other predefined functions may be removed if those configurations are not used or supported by at least one instantiation of the system design, functions that calculate and output values at a lower level which are not later used at a higher level may be removed, and/or the like. In these ways, the method 110 provides just one suitable example of a reduction technique that may be implemented by the RTL-to-RTL compiler 62.

Turning now to a related aspect of the present disclosure, the reduction techniques used herein may also be used with graphical user interfaces (GUIs). FIG. 6 is a flowchart depicting a method 130 of generating RTL suggestions for a graphical user interface (GUI). Although the following description of the method 130 is described as being performed by the client device 66 of FIG. 3, it should be noted that any suitable device or program capable of receiving and processing data may perform the method 130 described herein. In addition, although the method 130 is described in a particular order, it should be understood that the method 130 may be performed in any suitable order and may exclude one or more of the blocks described herein.

At block 132 the client device 66 may receive RTL code. In some situations, a designer may type the RTL code into a text-editor. Likewise, the designer may type the RTL code into an application associated with design software 18. As the designer types the RTL code, the client device 66 may present the RTL code on a GUI that may be associated with the text-editor and/or design software 18.

At block 134, the client device may generate a suggestion to change the RTL code based on one or more reduction techniques. As described above, the reduction techniques may be applied to RTL code before it is compiled. As a result, any of the reduction techniques described above that may use pattern analysis and/or leverage HDL syntax to remove or modify portions of an RTL file may be applied on the GUI as a designer types the RTL code (e.g., for a system design).

At block 136, the client device 66 may cause the suggestion to be presented on the GUI. In some aspects, the suggestion may include substitute RTL code or modifications to RTL code. Additionally or alternatively, the suggestion may include an explanation for a suggested change. In some cases, the suggestion may be implemented in a separate window or a separate affordance on the GUI. One benefit of providing the reduction techniques at this stage is that the designer may implement any feedback before compiling the RTL code. Indeed, after compiling the RTL code, the designer may not have an ability to return to the RTL level (e.g., after the RTL code is synthesized and/or processed into gates). Thus, providing the designer with suggestions while the designer is drafting the RTL code may provide greater flexibility to the designer to improve the RTL code (e.g., a system design) before compiling the RTL code. In this way, the designer may receive real time feedback for both improving a system design and increasing their knowledge.

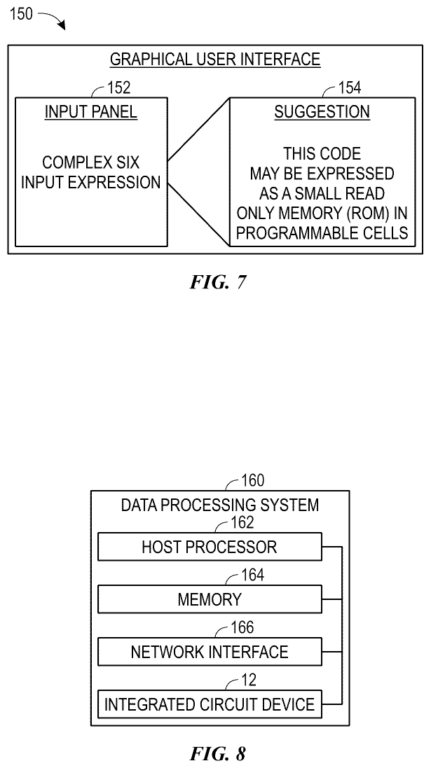

Turning now to an example, FIG. 7 is an example of a GUI that displays RTL suggestions, such as the RTL suggestions generated in the FIG. 6 flowchart. In this example, the GUI 150 includes an input panel 152 where the designer may type out RTL code. In this case, the designer may have implemented a complex six input expression in an HDL in the input panel 152. In response, the client device 66 may have generated a suggestion 154 to replace the complex expression with a small read only memory (ROM) in programmable cells of the programmable logic device. This suggestion 154 may be based on a predefined reduction technique that identifies certain complex expressions (e.g., based on pattern recognition) and substitutes in a small ROM to increase processing speed and/or flexibility. This example is intended to show one additional or alternative way that the reduction techniques may be used with a GUI to further improve system design and/or designer experience.

With the preceding in mind, the integrated circuit device 12 discussed above may be a component included in a data processing system, such as a data processing system 160, shown in FIG. 8. The data processing system 160 may include the integrated circuit device 12 (e.g., a programmable logic device, an application specific integrated circuit (ASIC)), a host processor 162, memory and/or storage circuitry 164, and a network interface 166. The data processing system 160 may include more or fewer components (e.g., electronic display, user interface structures, application specific integrated circuits (ASICs)). Moreover, any of the circuit components depicted in FIGS. 4, 6, and 8 may include the NOC 46 of the integrated circuit device 12. The host processor 162 may include any of the foregoing processors that may manage a data processing request for the data processing system 160 (e.g., to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 164 may include random access memory (RAM), read-only memory (ROM), one or more hard drives, flash memory, or the like. The memory and/or storage circuitry 164 may hold data to be processed by the data processing system 160. In some cases, the memory and/or storage circuitry 164 may also store configuration programs (e.g., bitstreams) for programming the integrated circuit device 12. The network interface 166 may allow the data processing system 160 to communicate with other electronic devices. The data processing system 160 may include several different packages or may be contained within a single package on a single package substrate. For example, components of the data processing system 160 may be located on several different packages at one location (e.g., a data center) or multiple locations. For instance, components of the data processing system 160 may be located in separate geographic locations or areas, such as cities, states, or countries.

The data processing system 160 may be part of a data center that processes a variety of different requests. For instance, the data processing system 160 may receive a data processing request via the network interface 166 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. To provide only a few examples, these may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. A method comprising:
receiving a Register-Transfer Level (RTL) file comprising a system design associated with a programmable logic device;
parsing the RTL file to generate a reduced RTL file based on removing one or more programmable logic block configurations not included in the system design; and
providing the reduced RTL file to a simulator tool.
EXAMPLE EMBODIMENT 2. The method of example embodiment 1, wherein parsing RTL file comprises:
generating a parse tree based on the RTL file; and
pruning one or more branches of the parse tree that cannot be reached by the simulator tool based on the system design.
EXAMPLE EMBODIMENT 3. The method of example embodiment 1, wherein generating the reduced RTL file comprises identifying a conditional statement in the RTL file and removing a branch of the conditional statement in the reduced RTL file.
EXAMPLE EMBODIMENT 4. The method of example embodiment 3, comprising evaluating the conditional statement based on one or more known values.
EXAMPLE EMBODIMENT 5. The method of example embodiment 1, wherein the system design comprises a syntax error, and the method comprises generating the reduced RTL file based on one or more portions of the system design that are not affected by the syntax error.
EXAMPLE EMBODIMENT 6. The method of example embodiment 1, wherein the RTL file comprises a plurality of vendor provided simulation models, and wherein each vendor provided simulation model of the plurality of vendor provided simulation models comprises a plurality of configurations for a respective plurality of programmable logic blocks included in the system design.
EXAMPLE EMBODIMENT 7. The method of example embodiment 6, wherein generating the reduced RTL file comprises substituting at least one function in the RTL file for an alternative function.
EXAMPLE EMBODIMENT 8. The method of example embodiment 1, comprising parsing a portion of the system design while simultaneously generating a portion of the reduced RTL file.
EXAMPLE EMBODIMENT 9. A non-transitory, computer-readable medium, comprising computer-readable instructions that, when executed by one or more processors of one or more computers, cause the one or more computers to:
receive a Register-Transfer Level (RTL) file comprising a system design for implementing a plurality of programmable logic blocks on a programmable logic device;
generate a modified RTL file by parsing the RTL file to remove a portion of a generic simulation model included in the system design, wherein the portion of the generic simulation model comprises a configuration for a programmable logic block of the plurality of programmable logic blocks that will not be reached during a behavioral simulation of the system design; and
transmit the modified RTL file to a simulator tool.
EXAMPLE EMBODIMENT 10. The non-transitory, computer-readable medium of example embodiment 9, wherein generating the modified RTL file comprises replacing the portion of the generic simulation model with an alternative RTL expression.
EXAMPLE EMBODIMENT 11. The non-transitory, computer-readable medium of example embodiment 9, wherein the computer-readable instructions cause the one or more computers to identify a conditional statement in the RTL file and remove at least one branch of the conditional statement in the modified RTL file.
EXAMPLE EMBODIMENT 12. The non-transitory, computer-readable medium of example embodiment 11, wherein the computer-readable instructions cause the one or more computers to identify a known value associated with a parameter of the conditional statement.
EXAMPLE EMBODIMENT 13. The non-transitory, computer-readable medium of example embodiment 9, wherein the plurality of programmable logic blocks comprise at least one intellectual property (IP) block retrieved from an IP parameterization tool.
EXAMPLE EMBODIMENT 14. The non-transitory, computer-readable medium of example embodiment 9, wherein the RTL file comprises an incomplete RTL file, and the computer-readable instructions cause the one or more computers to generate the modified RTL file based on a complete portion of the RTL file.
EXAMPLE EMBODIMENT 15. The non-transitory, computer-readable medium of example embodiment 9, wherein the RTL file comprises a syntax error, and the computer-readable instructions cause the one or more computers to generate the modified RTL file based on a portion of the RTL file that is not affected by the syntax error.
EXAMPLE EMBODIMENT 16. A system comprising:
a Register-Transfer Level (RTL)-to-RTL compiler comprising:
   processing circuitry; and
   a non-transitory, computer-readable medium, comprising computer-readable instructions that, when executed by the processing circuitry, causes the processing circuitry to:
      receive a first RTL file comprising an instantiation of an embedded programmable logic block;
      parse the first RTL file to identify one or more configurations of the embedded programmable logic block that are unrelated to the instantiation of the embedded programmable logic block; and
      remove the one or more configurations of the embedded programmable logic block from the first RTL file to generate a second RTL file; and
a simulator tool configured to receive the second RTL file from the RTL-to-RTL compiler and simulate a performance of a programmable logic device based on the second RTL file.
EXAMPLE EMBODIMENT 17. The system of example embodiment 16, wherein the embedded programmable logic block comprises a digital signal processing (DSP) block or a memory block.
EXAMPLE EMBODIMENT 18. The system of example embodiment 16, wherein the first RTL file comprises a plurality of configurations of the embedded programmable logic block based on a vendor provided simulation model.
EXAMPLE EMBODIMENT 19. The system of example embodiment 16, wherein the simulator tool comprises a behavioral instance model.
EXAMPLE EMBODIMENT 20. The system of example embodiment 16, wherein identifying the one or more configurations of the embedded programmable logic block that are unrelated to the instantiation of the embedded programmable logic block comprises determining that the one or more configurations correspond to a function of the embedded programmable logic block that is not used in the instantiation of the embedded programmable logic block.

What is claimed is:

1. A method comprising:
receiving a Register-Transfer Level (RTL) file comprising a system design associated with a programmable logic device;
parsing the RTL file to generate a reduced RTL file based on removing one or more programmable logic block configurations not included in the system design; and
providing the reduced RTL file to a simulator tool.

2. The method of claim 1, wherein parsing RTL file comprises:
generating a parse tree based on the RTL file; and
pruning one or more branches of the parse tree that cannot be reached by the simulator tool based on the system design.

3. The method of claim 1, wherein generating the reduced RTL file comprises identifying a conditional statement in the RTL file and removing a branch of the conditional statement in the reduced RTL file.

4. The method of claim 3, comprising evaluating the conditional statement based on one or more known values.

5. The method of claim 1, wherein the system design comprises a syntax error, and the method comprises generating the reduced RTL file based on one or more portions of the system design that are not affected by the syntax error.

6. The method of claim 1, wherein the RTL file comprises a plurality of vendor provided simulation models, and wherein each vendor provided simulation model of the plurality of vendor provided simulation models comprises a plurality of configurations for a respective plurality of programmable logic blocks included in the system design.

7. The method of claim 6, wherein generating the reduced RTL file comprises substituting at least one function in the RTL file for an alternative function.

8. The method of claim 1, comprising parsing a portion of the system design while simultaneously generating a portion of the reduced RTL file.

9. A non-transitory, computer-readable medium, comprising computer-readable instructions that, when executed by one or more processors of one or more computers, cause the one or more computers to:
receive a Register-Transfer Level (RTL) file comprising a system design for implementing a plurality of programmable logic blocks on a programmable logic device;
generate a modified RTL file by parsing the RTL file to remove a portion of a generic simulation model included in the system design, wherein the portion of the generic simulation model comprises a configuration for a programmable logic block of the plurality of programmable logic blocks that will not be reached during a behavioral simulation of the system design; and
transmit the modified RTL file to a simulator tool.

10. The non-transitory, computer-readable medium of claim 9, wherein generating the modified RTL file comprises replacing the portion of the generic simulation model with an alternative RTL expression.

11. The non-transitory, computer-readable medium of claim 9, wherein the computer-readable instructions cause the one or more computers to identify a conditional statement in the RTL file and remove at least one branch of the conditional statement in the modified RTL file.

12. The non-transitory, computer-readable medium of claim 11, wherein the computer-readable instructions cause the one or more computers to identify a known value associated with a parameter of the conditional statement.

13. The non-transitory, computer-readable medium of claim 9, wherein the plurality of programmable logic blocks comprise at least one intellectual property (IP) block retrieved from an IP parameterization tool.

14. The non-transitory, computer-readable medium of claim 9, wherein the RTL file comprises an incomplete RTL file, and the computer-readable instructions cause the one or more computers to generate the modified RTL file based on a complete portion of the RTL file.

15. The non-transitory, computer-readable medium of claim 9, wherein the RTL file comprises a syntax error, and the computer-readable instructions cause the one or more computers to generate the modified RTL file based on a portion of the RTL file that is not affected by the syntax error.

16. A system comprising:
a Register-Transfer Level (RTL)-to-RTL compiler comprising:
processing circuitry; and
a non-transitory, computer-readable medium, comprising computer-readable instructions that, when executed by the processing circuitry, causes the processing circuitry to:
receive a first RTL file comprising an instantiation of an embedded programmable logic block;
parse the first RTL file to identify one or more configurations of the embedded programmable logic block that are unrelated to the instantiation of the embedded programmable logic block; and
remove the one or more configurations of the embedded programmable logic block from the first RTL file to generate a second RTL file; and
a simulator tool configured to receive the second RTL file from the RTL-to-RTL compiler and simulate a performance of a programmable logic device based on the second RTL file.

17. The system of claim 16, wherein the embedded programmable logic block comprises a digital signal processing (DSP) block or a memory block.

18. The system of claim 16, wherein the first RTL file comprises a plurality of configurations of the embedded programmable logic block based on a vendor provided simulation model.

19. The system of claim 16, wherein the simulator tool comprises a behavioral instance model.

20. The system of claim 16, wherein identifying the one or more configurations of the embedded programmable logic block that are unrelated to the instantiation of the embedded programmable logic block comprises determining that the one or more configurations correspond to a function of the embedded programmable logic block that is not used in the instantiation of the embedded programmable logic block.
